(19) United States
(12) Patent Application Publication
(10) Pub. No.: US 2025/0252550 A1
(43) Pub. Date: Aug. 7, 2025

(54) METHOD AND SYSTEM FOR RETRIEVING DIFFRACTION PARAMETER OF PHOTOMASK

(71) Applicant: TAIWAN SEMICONDUCTOR MANUFACTURING COMPANY LTD., HSINCHU (TW)

(72) Inventors: KENJI YAMAZOE, SAN JOSE, CA (US); CHIEN LIN CHEN, TAINAN CITY (TW); JYUN-HONG CHEN, TAICHUNG CITY (TW); YEN HUI HSIEH, NEW TAIPEI CITY (TW); CHEN SHUAI, TAOYUAN CITY (TW); TZU-CHUN LO, HSINCHU CITY (TW)

(21) Appl. No.: 18/433,275

(22) Filed: Feb. 5, 2024

(51) Int. Cl. G06T 7/00; G03F 1/70; G06T 11/00

(52) U.S. Cl. CPC G06T 7/0006; G03F 1/70; G06T 7/001; G06T 11/00; G06T 2207/10056; G06T 2207/20048; G06T 2207/30148

(57) ABSTRACT

The present disclosure provides a method and a system for retrieving diffraction parameter of a photomask. The method includes: determining at least one first diffraction parameter of a first rasterized photomask image corresponding to a photomask; determining a digital microscope simulation image according to the at least one first diffraction parameter; comparing the digital microscope simulation image with a captured image to generate a difference image, wherein the captured image is generate by an image capture device equipped with the photomask; determining a second rasterized photomask image according to the first rasterized photomask image, the difference image and the at least one first diffraction parameter; and determining at least one second diffraction parameter of the second rasterized photomask image.

### BACKGROUND

During semiconductor producing procedure, a photomask is fabricated for optical lithography process. After the photomask is fabricated, there may be unexpected defect(s) on the photomask. In some cases, the defect(s) may be printed on the wafer, whereas the defect(s) may not be printed on the wafer in other cases. Regarding the cases that the defect(s) is/are printed on the wafer, the photomask needs to be re-fabricated. Regarding the cases that the defect(s) is/are not printed on the wafer, the photomask does not need to be re-fabricated. Whether the defect(s) is/are printed on the wafer affects semiconductor producing procedure.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a block diagram of a system, in accordance with some embodiments of the present disclosure.

FIGS. 2A and 2B illustrate schematic views of simulating a wafer image and determining whether the wafer image has a printed defect with respect to a photomask, in accordance with some embodiments of the present disclosure.

FIGS. 3A to 3I are schematic views illustrating images relate to diffraction parameters optimization and defect determination, in accordance with some embodiments of the present disclosure.

FIGS. 4A to 4I are schematic views illustrating images relate to diffraction parameters optimization and defect determination, in accordance with some embodiments of the present disclosure.

FIGS. 5A to 5F are flowcharts of a method, in accordance with some embodiments of the present disclosure.

FIGS. 6A to 6C are flowcharts of a method, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

According to the disclosure, after a photomask for optical lithography process is fabricated, an image of printed wafer corresponding to the photomask may be simulated and the simulated image may be compared with an original design image of the photomask for determining whether potential defect(s) of the photomask is/are printed on a wafer.

In addition, to precisely simulate the image of the printed wafer, the physical property such as diffraction parameters related to the photomask may be significant. In some cases, diffraction parameters related to the photomask may be obtained based on a captured image of the photomask using Fourier Transform (FT)-related formula, and optimized diffraction parameters of the photomask may be obtained based on a lot of captured images of the photomask and the corresponding diffractions. However, the costs of capturing images and calculating optimized diffraction parameters based on the larger number of captured images are heavy. According to the disclosure, fewer capturing image may be introduced for efficiently and correctly retrieving optimized diffraction parameters of the photomask.

According to the disclosure, diffraction parameters may be optimized based on the following steps: (1) generating a rasterized photomask image corresponding to a photomask; (2) retrieving diffraction parameters of the photomask according to the rasterized photomask image; (3) generating a digital microscope simulation image according to the retrieved diffraction parameters; (4) comparing the digital microscope simulation image with a captured image of the photomask captured by an image capture device equipped with the photomask (e.g., the captured image may be captured by a digital microscope which has the photomask disposed between an illumination of the digital microscope and a photosensitive element, such as charge coupled device, of the digital microscope); (5) determining whether the digital microscope simulation image and the captured image are similar. When the digital microscope simulation image and the captured image are determined similar (i.e., the digital microscope simulation image is proximate to the real capture image), it means that the parameters (e.g., the diffraction parameters) used for the digital microscope simulation image may be proximate to the parameters (e.g., the diffraction parameters) applied to the real capture image. Therefore, the diffraction parameters of the digital microscope simulation image may be the optimized diffraction parameters. When the digital microscope simulation image and the captured image are determined dissimilar (i.e., the digital microscope simulation image is not proximate to the real capture image), it means that the parameters (e.g., the diffraction parameters) used for the digital microscope simulation image may not be proximate to the parameters (e.g., the diffraction parameters) applied to the real capture image. Therefore, the rasterized photomask image may be updated based on the diffraction parameters and the digital microscope simulation image, and steps (1) to (5) may be performed with the updated rasterized photomask image until the optimized diffraction parameters are determined. After determining the optimized diffraction parameters, the optimized diffraction parameters may be used for simulating a scanner simulation image which is a simulation image of a scanner equipped with the photomask. The scanner simulation image may be compared with an original design image of the photomask to determine whether the scanner simulation image has a printable defect with respect to the photomask. The detail of the disclosure will be further described below.

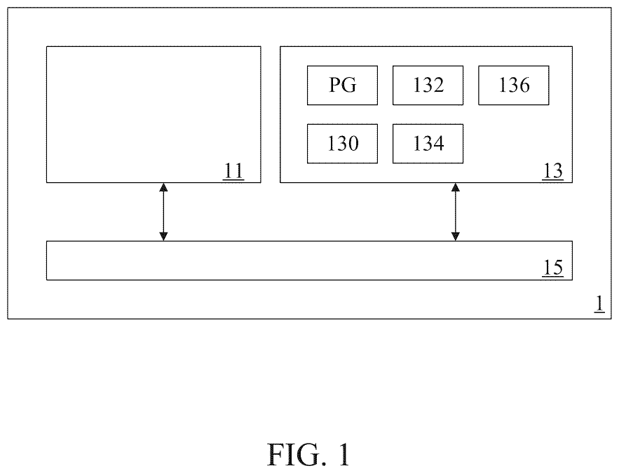

FIG. 1 illustrates a block diagram of a system 1 according to some embodiments of the present disclosure. The system 1 includes a processor 11 and a storing unit 13. The storing unit 13 may store a diffraction retrieve model 130, a digital microscope image simulation model 132, a rasterized photomask image generation model 134 and a scanner image simulation model 136. The diffraction retrieve model 130 may receive a rasterized photomask image corresponding to a photomask and generate at least one diffraction parameter of the rasterized photomask image. The digital microscope image simulation model 132 may receive diffraction parameters and generate a digital microscope simulation image. The rasterized photomask image generation model 134 may receive: (1) the rasterized photomask image, (2) a difference image of the digital microscope simulation image and a capture image of the photomask captured by an image capture device equipped with the photomask and (3) one or more diffraction parameters, and generate an updated rasterized photomask image based on the abovementioned images and diffraction parameters.

In some embodiments, the diffraction retrieve model 130 may include a following Fourier Transform (FT)-related formula:

[symbol]

=FT[m^{k}(x,y)]

where m^{k}(x, y) is a rasterized photomask image of a photomask and [symbol] at least one diffraction parameter of the photomask. Coordinate (x, y) and (f, g) are under FT relationship; (x, y) is often called real space coordinate and (f, g) is called Fourier space coordinate or spatial frequency. In some embodiments, to obtain \hat{m}^{xx}(f, g), [symbol] may be weighted by

$$\frac{d}{d x} {m}^{k} ( x , y ) .$$

To obtain \hat{m}^{yy}(f, g), [symbol] may be weighted by d/dym^{k}(x, y).

In some embodiments, the digital microscope image simulation model 132 may include following formula:

$$I ( x , y ) = {\sum }_{i = 1}^{N} {λ}_{i} {\vert {FT}^{- 1} [ {Φ}_{i}^{x x} ( f , g ) {\hat{m}}^{x x} ( f , g ) + {Φ}_{i}^{y y} ( f , g ) ( f , g ) {\hat{m}}^{y y} ( f , g ) ] \vert}^{2}$$

I(x, y) is a digital microscope simulation image corresponding to a photomask, λᵢ is the i-th eigenvalue of transmission cross coefficient (TCC.) Φᵢ^{xx}(f, g) is the i-th TCC eigenfunction for modulating \hat{m}^{xx}·\hat{m}^{xx}(f, g) is a diffraction parameter about an illumination light diffracted by the photomask and reached the pupil plane as X-polarized light when the illumination light polarized in X-direction. Φᵢ^{yy}(f, g) is the i-th TCC eigenfunction for modulating \hat{m}^{yy}(f, g), \hat{m}^{yy}(f, g) is a diffraction parameter about an illumination light diffracted by the photomask and reached the pupil plane as Y-polarized light when the illumination light polarized in Y-direction. In some cases, Φᵢ^{xx}(f, g) and Φᵢ^{yy}(f, g) may be calculated based on a set of parameters (e.g., illumination, illumination polarization, wavelength, numerical aperture, mask stack, magnification, Charge-Coupled Device (CCD) pixel size) of a digital microscope device equipped with the photomask, and the calculations of Φᵢ^{xx}(f, g) and Φᵢ^{yy}(f, g) are well known. N is an integer to decide how many TCC eigenvalues and eigenfunctions are used. In some embodiments, N is equal or smaller than 128.

In some embodiments, λᵢ, Φᵢ^{xx}(f, g) and Φᵢ^{yy}(f, g) related to the photomask are calculable parameters according to the set of parameters (e.g., illumination, illumination polarization, wavelength, numerical aperture, mask stack, magnification, CCD pixel size) of the digital microscope equipped with the photomask. Accordingly, the digital microscope simulation image corresponding to the photomask may be generated according to the above formula. In some cases, TCC eigenfunction (e.g., Φᵢ^{xx}(f, g) and Φᵢ^{yy}(f, g)) and TCC eigenvalue (e.g., λᵢ) may be mathematically decomposed by the following general formula:

$$TCC ( {f}_{1} , {g}_{1} {f}_{2} , {g}_{2} ) = {\sum }_{i} {λ}_{i} {Φ}_{i} ( {f}_{1} , {g}_{1} ) {Φ}_{i} * ( {f}_{2} , {g}_{2} )$$

In some embodiments, the rasterized photomask image generation model 134 may include following formula:

$${m}^{k + 1} ( x , y ) = {m}^{k} ( x , y ) - α \frac{d F}{d m} ( x , y )$$

where during an iterative optimization procedure, the output m^{k+1}(x, y) is the (k+1)-th rasterized photomask image, while the input m^{k}(x, y) is the k-th rasterized photomask image, α is a predetermined constant and F is a loss function of the image function m(x,y) as expressed below:

$$\frac{d F}{d m} = [ {I}^{k} ( x , y ) - {I}_{t} ( x , y ) ] \frac{dI}{d m}$$

where the image I^{k}(x, y) is the k-th digital microscope simulation image corresponding to the photomask and the image Iₜ(x, y) is a captured image of the photomask by the digital microscope device equipped with the photomask (i.e., the image Iₜ(x, y) is an image captured by the digital microscope capture device which has the photomask disposed between an illumination of the digital microscope and a photosensitive element, such as CCD, of the digital microscope device). According to the rasterized photomask image generation model 134 which may be a gradient formula, optimized m^{j}(x, y) may be reached when loss function F is minimized. In some cases, when corresponding I^{j}(x, y) approximates to Iₜ(x, y) which means that I^{j}(x, y) and Iₜ(x, y) are similar, loss function F may be minimized and m^{j}(x, y) may be optimized.

In some embodiments, the scanner image simulation model 136 may include following formula:

$${I}_{s canner} ( x , y ) = {\sum }_{i = 1}^{N} {λ}_{i} {\vert {FT}^{- 1} [ Φ {s}_{i}^{x x} ( f , g ) {\hat{m}}_{o}^{x x} ( f , g ) + Φ {s}_{i}^{y y} ( f , g ) ( f , g ) {\hat{m}}_{o}^{y y} ( f , g ) ] \vert}^{2}$$

I_{scanner}(x, y) is a scanner simulation image corresponding to the photomask. λᵢ is the i-th eigenvalue of TCC. Φsᵢ^{xx}(f, g) and Φsᵢ^{yy}(f, g) are the i-th TCC eigenfunctions. \hat{m}ₒ^{xx}(f, g) and \hat{m}ₒ^{yy}(f, g) are optimized diffraction parameters corresponding to the photomask. In some cases, Φsᵢ^{xx}(f, g) and Φsᵢ^{yy}(f, g) may be calculated based on a set of parameters (e.g., illumination, illumination polarization, wavelength, numerical aperture, mask stack, magnification, resist model) of a scanner device equipped with the photomask, and the calculations of Φsᵢ^{xx}(f, g) and Φsᵢ^{yy}(f, g) are well known. Lastly, N is an integer to decide how many TCC eigenvalues and eigenfunctions are used. Typically, N is equal or smaller than 128. In some cases, the decomposition of TCC eigenfunction (e.g., Φsᵢ^{xx}(f, g) and Φsᵢ^{yy}(f, g)) and TCC eigenvalue (e.g., λᵢ) may refer to the mentioned general formula, and the detail of obtaining λᵢ, Φsᵢ^{xx}(f, g) and Φsᵢ^{yy}(f, g) based on the set of parameters of the scanner may refer to mentioned references.

Throughout the present disclosure, for any of the formulae and parameters, an image symbol appended with pixel coordinates (x, y) of the image (e.g., the rasterized photomask image m^{k}(x, y), the digital microscope simulation image I(x, y), the capture image Iₜ(x, y), and the scanner simulation image I_{scanner}(x, y)) may refer to the entire image, i.e., the image including all pixels with corresponding valid coordinates (x, y).

In some embodiments, the processor 11 and the storing unit 13 are electrically coupled through a communication bus 15. The communication bus 15 may allow the processor 11 to execute a program PG stored in the storing unit 13. When executed, the program PG may generate one or more interrupts (e.g., software-interrupt) to cause the processor 11 to perform functions of the program PG for simulating the wafer image and determining whether the wafer image has a printed defect with respect to a photomask. The functions of the program PG will be further described hereinafter.

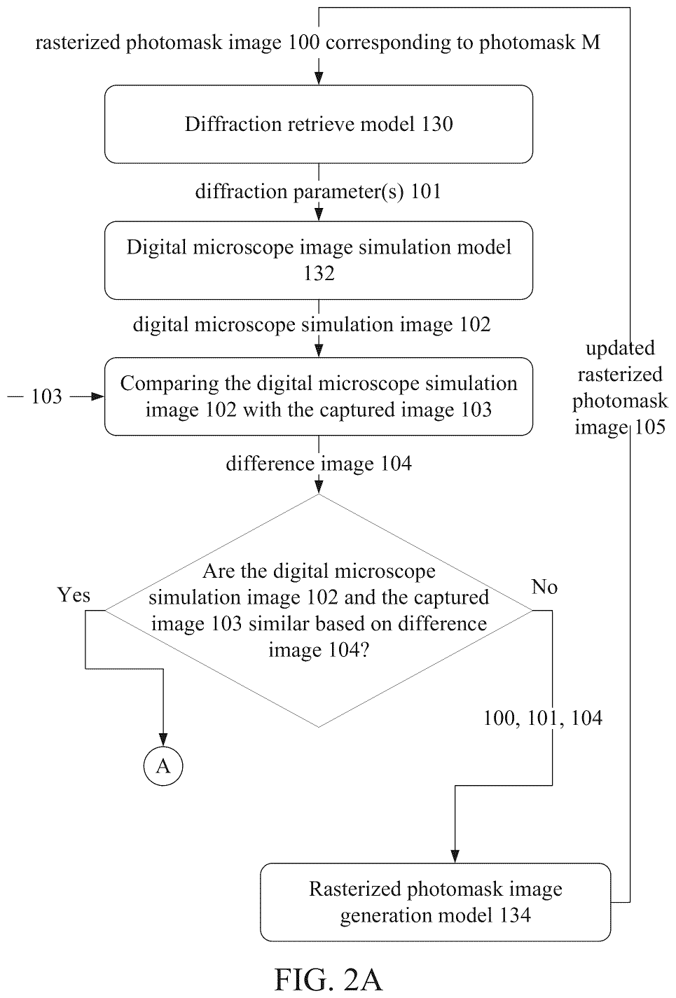

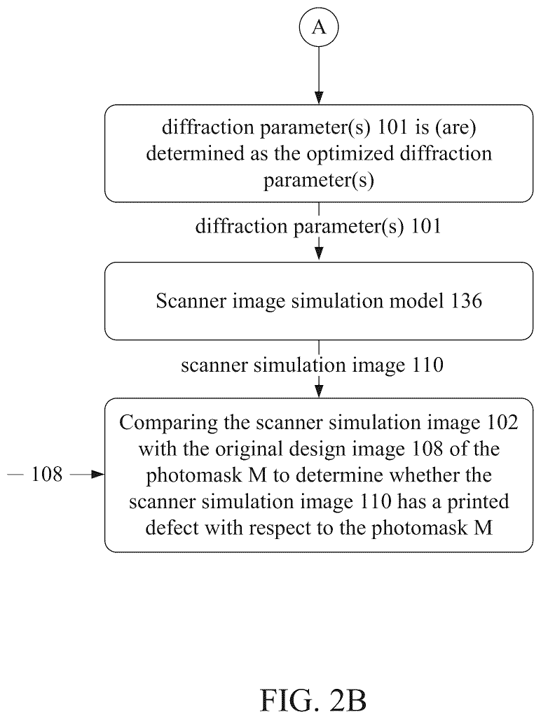

FIGS. 2A and 2B illustrate schematic views of optimizing diffraction parameters of a photomask and determining whether a simulated wafer image has a printed defect with respect to the photomask based on the optimized diffraction parameter. In some embodiments, the processor 11 may retrieve at least one diffraction parameter 101 based on a rasterized photomask image 100 of a photomask M using the diffraction retrieve model 130. In other words, the rasterized photomask image 100 may be inputted into the diffraction retrieve model 130 for outputting the at least one diffraction parameter 101.

The processor 11 may generate a digital microscope simulation image 102 according to the at least one diffraction parameter 101 using the digital microscope image simulation model 132. In other words, the at least one diffraction parameter 101 may be inputted into the digital microscope image simulation model 132 for outputting the digital microscope simulation image 102. The processor 11 may compare the digital microscope simulation image 102 with a captured image 103 to generate a difference image 104. The captured image 103 of the photomask M may be captured by an image capture device (not shown) equipped with the photomask M. For example, the image capture device may be a digital microscope device equipped with the photomask M for capturing image of the photomask M.

In some embodiments, some pixels of the digital microscope simulation image 102 and the coordinate-corresponding pixels of the captured image 103 may respectively be the same. Therefore, the coordinate-corresponding pixels of the difference image 104 may be “0” when the difference image 104 is obtained by subtracting the digital microscope simulation image 102 from the captured image 103. If a number of these coordinate-corresponding pixels of the difference image 104 is determined to be equal to or greater than a pre-determined threshold (i.e., if the digital microscope simulation image 102 and the captured image 103 are deemed highly similar), it means that the digital microscope simulation image 102 may be proximate to the real capture image 103 of the photomask M. Therefore, the at least one diffraction parameter 101 may be the optimized diffraction parameter of the photomask M, i.e., the at least one diffraction parameter 101 may be the real diffraction parameter of the photomask M.

In some embodiments, after the at least one diffraction parameter 101 is determined as the optimized diffraction parameter(s) of the photomask, the processor 11 may generate a scanner simulation image 110 according to the at least one diffraction parameter 101 using the scanner image simulation model 136. In other words, the at least one diffraction parameter 101 may be inputted into the scanner image simulation model 136 for outputting the scanner simulation image 110. The scanner image simulation model 136 is used for simulating image of wafer captured by a scanner (e.g., exposure tool) equipped with the photomask M.

The processor 11 may compare the scanner simulation image 110 with an original design image 108 (e.g., graphical data system (GDS) II format image) of the photomask M to determine whether the scanner simulation image 110 has a printed defect with respect to the photomask M. Because the scanner simulation image 110 may be proximate to the printed wafer using the photomask M, the printed wafer using the photomask M may have defect when the scanner simulation image 110 is determined having a printed defect with respect to the photomask M.

In some embodiments, if the number of these coordinate-corresponding pixels of the difference image 104 is determined to be less than the pre-determined threshold (i.e., if the digital microscope simulation image 102 and the captured image 103 are deemed dissimilar), the processor 11 may generate an updated rasterized photomask image 105 according to the rasterized photomask image 100, the difference image 104 and the at least one diffraction parameter 101 using the rasterized photomask image generation model 134. In other words, the rasterized photomask image 100, the difference image 104 and the at least one diffraction parameter 101 may be inputted into the rasterized photomask image generation model 134 for outputting the updated rasterized photomask image 105. The updated rasterized photomask image 105 may then be set as the rasterized photomask image 100 in a next loop and the previously mentioned operations may be repeated until the optimized diffraction parameter(s) is/are determined.

In some embodiments, after determining the optimized diffraction parameters, the processor 11 may generate another simulation image according to the optimized diffraction parameter(s) using another image simulation model with different parameter settings. For example, the another simulation model may include following formula:

$${I}_{a nother} ( x , y ) = {\sum }_{i = 1}^{N} {λ}_{i} {\vert {FT}^{- 1} [ Φ {a}_{i}^{x x} ( f , g ) {\hat{m}}_{o}^{x x} ( f , g ) + Φ {a}_{i}^{y y} ( f , g ) ( f , g ) {\hat{m}}_{o}^{y y} ( f , g ) ] \vert}^{2}$$

Iₐₙₒₜₕₑᵣ(x, y) is a simulation image corresponding to the photomask M. λᵢ is the i-th eigenvalue of TCC. Φaᵢ^{xx}(f, g) and Φaᵢ^{yy}(f, g) are the i-th TCC eigenfunctions. \hat{m}ₒ^{xx}(f, g) and \hat{m}ₒ^{yy}(f, g) are optimized diffraction parameters 101 corresponding to the photomask M. In some cases, Φaᵢ^{xx}(f, g) and Φaᵢ^{yy}(f, g) may be calculated based on another set of parameters (e.g., illumination, illumination polarization, wavelength, numerical aperture, mask stack, magnification, resist model) of a scanner device equipped with the photomask M, and the calculations of Φaᵢ^{xx}(f, g) and Φaᵢ^{yy}(f, g) are well known. The simulation image may be used for confirming the correctness of the determination of printed defect with respect to the photomask M. For example, the printer defect could be very small so that the printer defect can be seen under some illumination settings but may not be visible under other illumination settings. Therefore, the illumination for calculating Φaᵢ^{xx}(f, g) and Φaᵢ^{yy}(f, g) is adjusted to be different from the illumination for calculating Φsᵢ^{xx}(f, g) and Φsᵢ^{yy}(f, g) so that the simulation image generated based on Φaᵢ^{xx}(f, g) and Φaᵢ^{yy}(f, g) can be compared with the original design image 108 to see if the printed defect exists under different illumination setting.

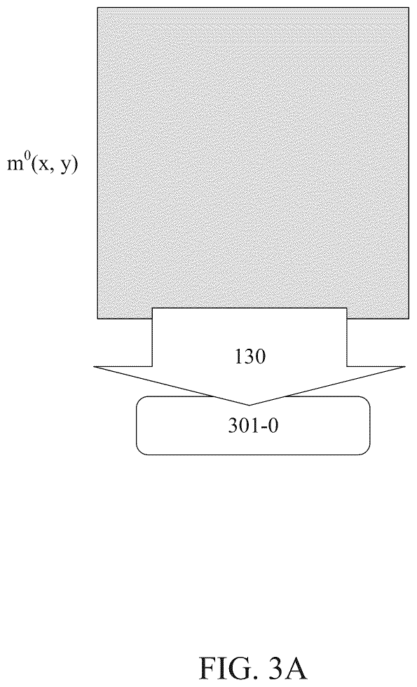

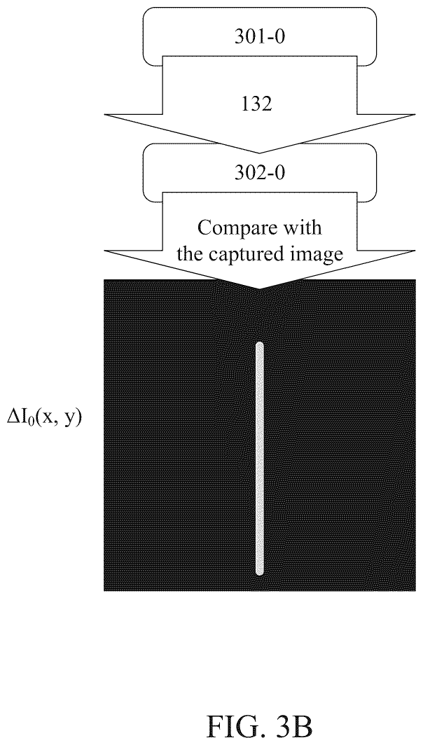

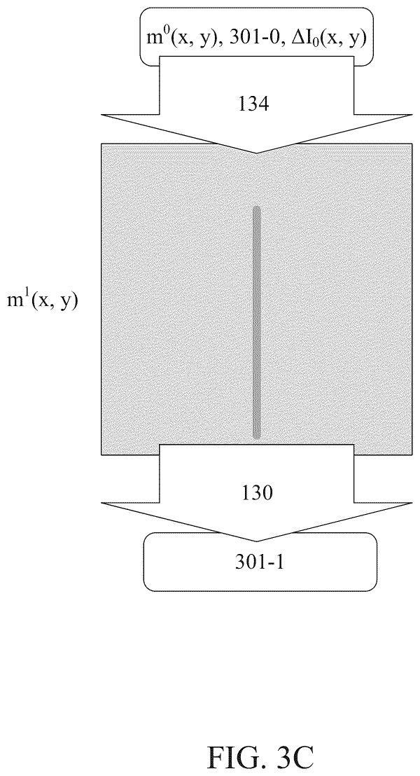

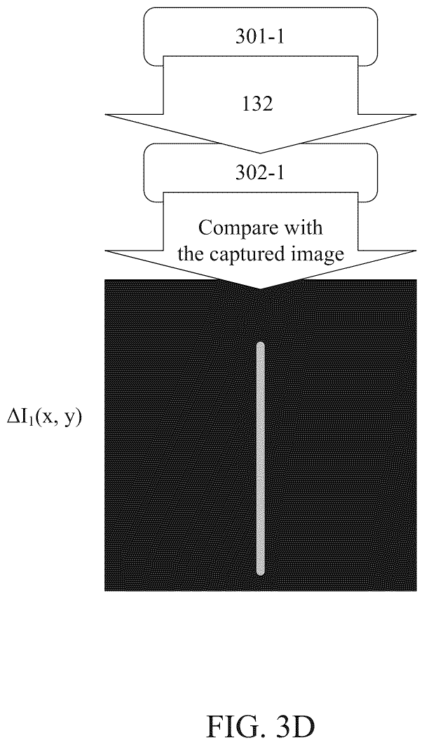

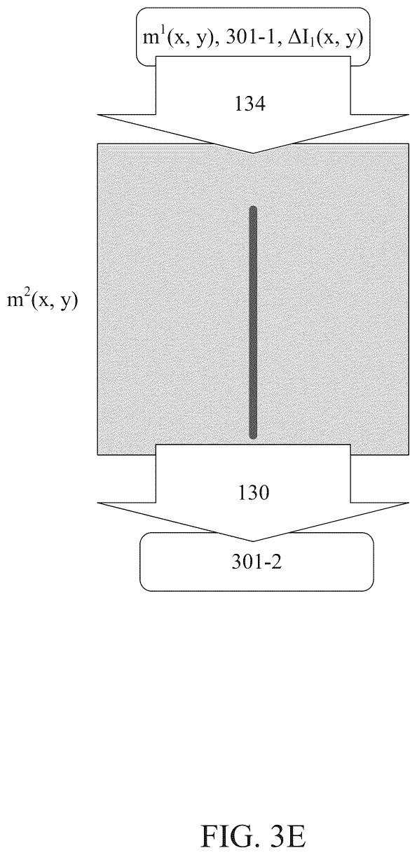

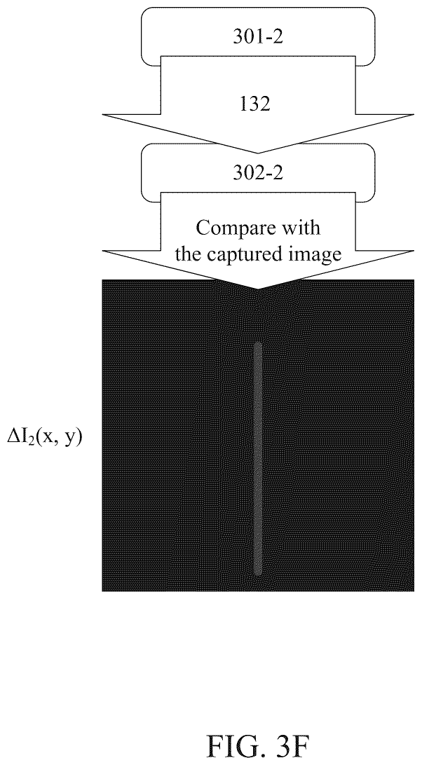

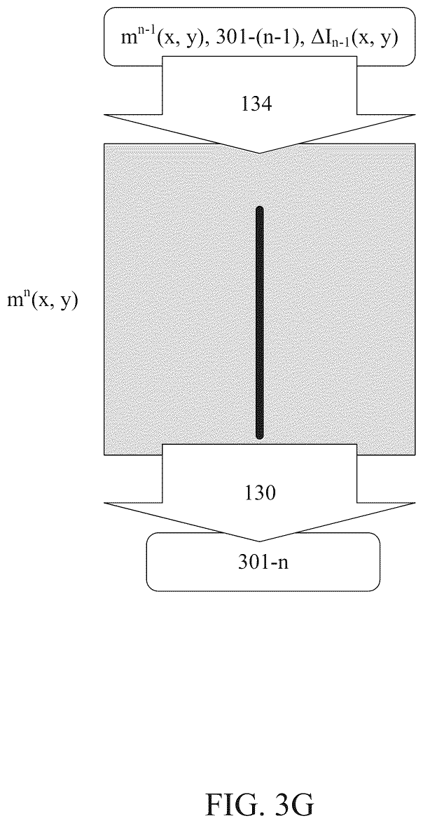

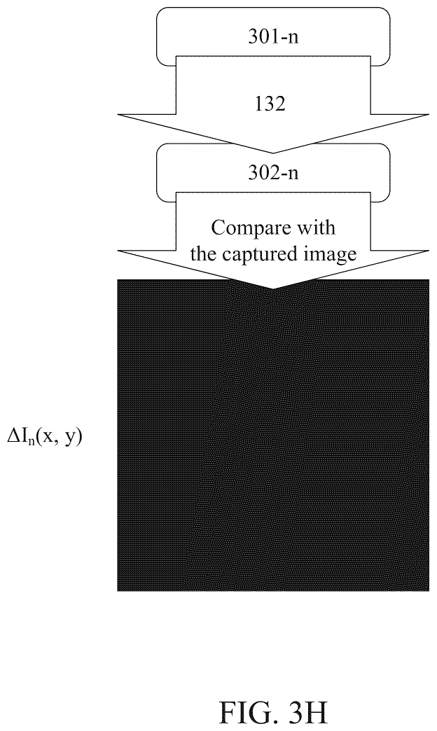

FIGS. 3A to 3I are schematic views illustrating images relate to diffraction parameters optimization and defect determination in accordance with some embodiments. In some embodiments, at an initial step, the processor 11 may determine an initial rasterized photomask image m⁰(x, y), as shown in FIG. 3A. Each pixel of the initial rasterized photomask image m⁰(x, y) may have the same value, for example, zero or one half of the maximal value. Then, the processor 11 may generate initial diffraction parameters 301-0 of the initial rasterized photomask image m⁰(x, y) using the diffraction retrieve model 130. The initial diffraction parameters 301-0 may include an X-direction diffraction parameter and a Y-direction diffraction parameter.

The processor 11 may generate an initial digital microscope simulation image 302-0 according to the initial diffraction parameters 301-0 using the digital microscope image simulation model 132, and then compare the initial digital microscope simulation image 302-0 with a captured image of a photomask to generate a difference image ΔI₀(x, y) as shown in FIG. 3B. For example, the processor 11 is configured to subtract pixel values of the initial digital microscope simulation image 302-0 by those of the captured image to generate the difference image ΔI₀(x, y). The processor 11 may yet further determine that the initial digital microscope simulation image 302-0 and the captured image are dissimilar according to the difference image ΔI₀(x, y).

As shown in FIG. 3C, the processor 11 may generate an updated rasterized photomask image m¹(x, y) according to the initial rasterized photomask image m⁰(x, y), the difference image ΔI₀(x, y) and the initial diffraction parameters 301-0 using the rasterized photomask generation model 134. Then, the processor 11 may generate diffraction parameters 301-1 of the rasterized photomask image m¹(x, y) using the diffraction retrieve model 130. The diffraction parameters 301-1 may include an X-direction diffraction parameter and a Y-direction diffraction parameter.

The processor 11 may generate a digital microscope simulation image 302-1 according to the diffraction parameters 301-1 using the digital microscope image simulation model 132, and then compare the digital microscope simulation image 302-1 with the captured image to generate a difference image ΔI₁(x, y), as shown in FIG. 3D The processor 11 may determine that the digital microscope simulation image 302-1 and the captured image are dissimilar according to the difference image ΔI₁(x, y). The processor 11 may generate an updated rasterized photomask image m²(x, y) according to the rasterized photomask image m¹(x, y), the difference image ΔI₁(x, y) and the diffraction parameters 301-1 using the rasterized photomask image generation model 134.

Then, the processor 11 may generate diffraction parameters 301-2 of the rasterized photomask image m²(x, y) using the diffraction retrieve model 130, as shown in FIG. 3E. The diffraction parameters 301-2 may include an X-direction diffraction parameter and a Y-direction diffraction parameter. The processor 11 may generate a digital microscope simulation image 302-2 according to the diffraction parameters 301-2 using the digital microscope image simulation model 132, and then compare the digital microscope simulation image 302-2 with the captured image to generate a difference image ΔI₂(x, y), as shown in FIG. 3F. The processor 11 may determine that the digital microscope simulation image 302-2 and the captured image are dissimilar according to the difference image ΔI₂(x, y). The processor 11 may generate an updated rasterized photomask image m³(x, y) according to the rasterized photomask image m²(x, y), the difference image ΔI₂(x, y) and the diffraction parameters 301-2 using the rasterized photomask image generation model 134.

Then, the processor 11 may repeatedly perform steps in FIGS. 3A to 3F to generate the n^{th} diffraction parameters 301-n of the n^{th} rasterized photomask image mⁿ(x, y), the n^{th} digital microscope simulation image 302-n and the n^{th} difference image ΔIₙ(x, y), as shown in FIGS. 3G and 3H, until the processor 11 determines that the similarity of the digital microscope simulation image 302-n and the captured image are within the predetermined threshold according to the difference image ΔIₙ(x, y). After determining that the similarity of the digital microscope simulation image 302-n and the captured image are within the predetermined threshold according to the difference image ΔIₙ(x, y), the processor 11 may determine that the rasterized photomask image m^{a}(x, y) is the optimized photomask image and the corresponding n^{th} diffraction parameters 301-n are the optimized diffraction parameters.

Referring to FIG. 3I, the processor 11 may generate a scanner simulation image 310 based on the optimized diffraction parameters 301-n using the scanner image simulation model 136 and compare the scanner simulation image 310 with an original design image 312 (e.g., in the GDS II format) of the photomask to determine whether the scanner simulation image 310 has a printable defect with respect to the photomask. In these embodiments, the scanner simulation image 310 may not have any printed defect with respect to the photomask so that the photomask does not need to be repaired or re-fabricated.

In some implementations, when the difference image ΔIₙ(x, y) represents that a difference ratio between the corresponding simulation image and the captured image is not less than a pre-determined threshold (e.g., 3%), it means that the corresponding simulation image and the captured image are not similar enough. When the difference image ΔIₙ(x, y) represents that the difference ratio between the corresponding simulation image and the captured image is less than the pre-determined threshold (e.g., 3%), it means that the corresponding simulation image and the captured image are similar enough. For example, the difference image ΔIₙ(x, y) has 100 pixels, and there are 60 pixels showing the same value “0”. Therefore, the difference ratio between the corresponding simulation image and the captured image is (100-60)/100=40%, which is not less than 3%. The corresponding simulation image and the captured image are not similar enough. In another example, the difference image ΔIₙ(x, y) has 100 pixels, and there are 98 pixels showing the same value “0”. Therefore, the difference ratio between the corresponding simulation image and the captured image is (100-98)/100=2% which is less than the threshold of 3%. The corresponding simulation image and the captured image are similar enough.

In some implementations, if a number of pixels of the difference image ΔIₙ(x, y) having the same value “0” is less than a pre-determined threshold (e.g., 90), it means that the initial simulation image and the captured image are not similar enough. If the number of pixels of the difference image ΔIₙ(x, y) having the same value “0” is equal to or greater than the pre-determined threshold (e.g., 90), it means that the initial simulation image and the captured image are similar enough. For example, the difference image ΔIₙ(x, y) has 100 pixels, and there are 60 pixels having the same value “0”. Therefore, the corresponding simulation image and the captured image are not similar enough because 60 is less than the pre-determined threshold 90. In another example, the difference image ΔIₙ(x, y) has 100 pixels, and there are 95 pixels having the same value “0”. Therefore, the corresponding simulation image and the captured image are similar enough because the number 95 is greater than the pre-determined threshold 90.

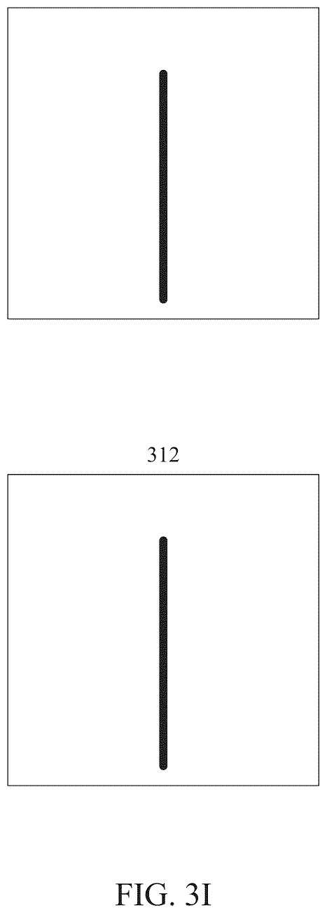

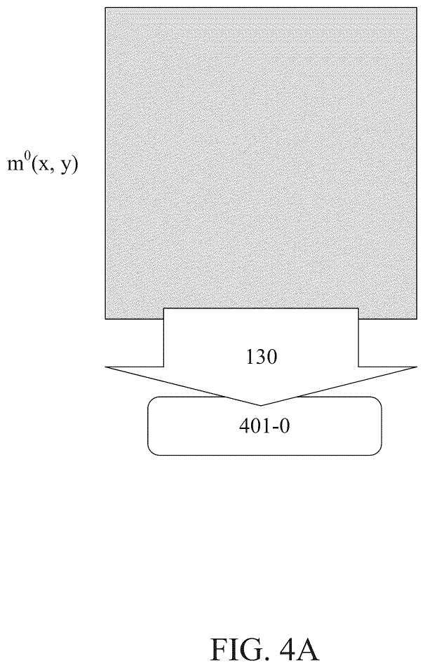

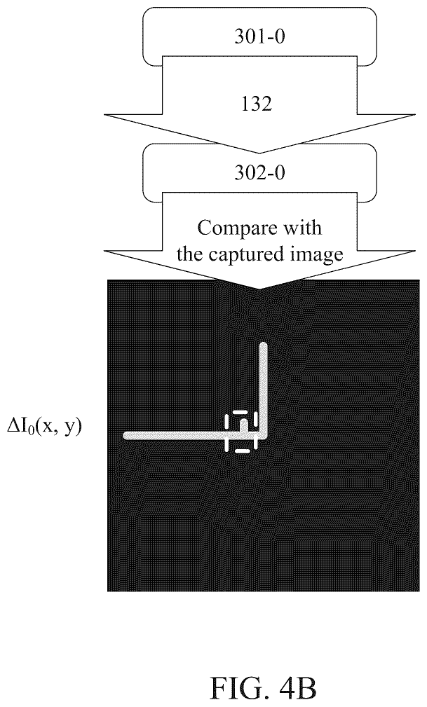

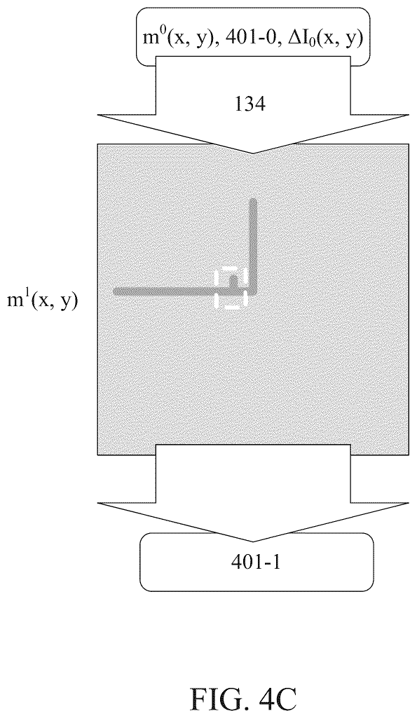

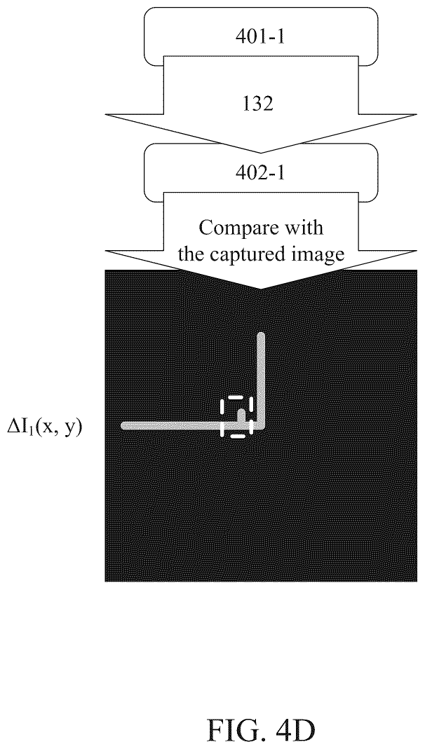

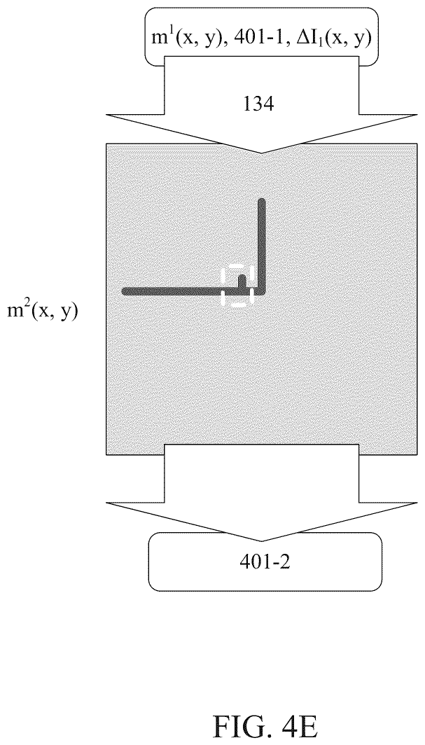

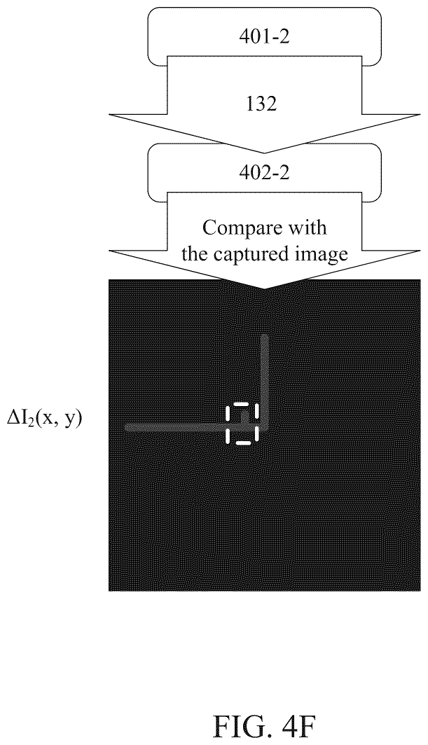

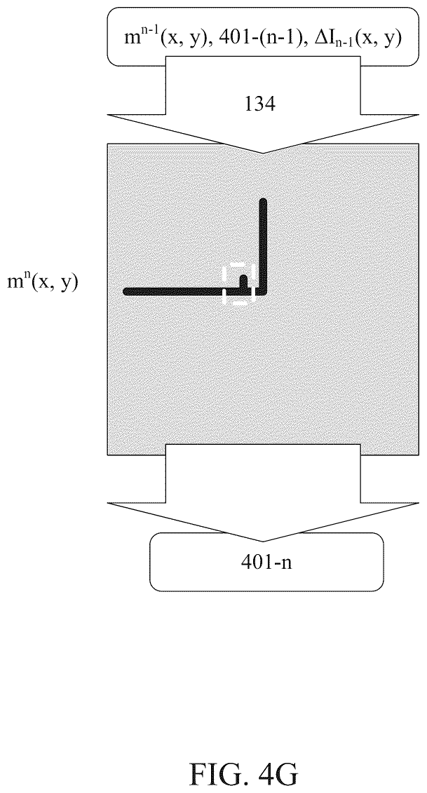

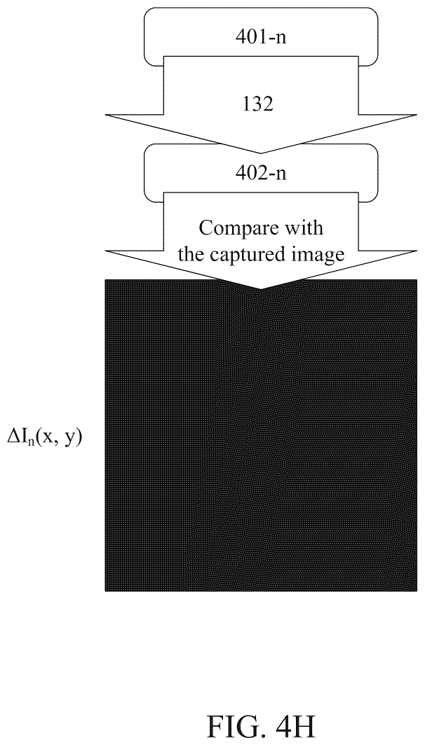

FIGS. 4A to 4I are schematic views illustrating images related to diffraction parameters optimization and defect determination in accordance with some embodiments. In some embodiments, at an initial step, the processor 11 may determine an initial rasterized photomask image m⁰(x, y), as shown in FIG. 4A. Each pixel of the initial rasterized photomask image m⁰(x, y) may have the same values, for example, zero or one half of the maximal value. Then, the processor 11 may generate initial diffraction parameters 401-0 of the initial rasterized photomask image m⁰(x, y) using the diffraction retrieve model 130. The initial diffraction parameters 401-0 may include an X-direction diffraction parameter and a Y-direction diffraction parameter.

The processor 11 may generate an initial digital microscope simulation image 402-0 according to the initial diffraction parameters 401-0 using the digital microscope image simulation model 132, and then compare the initial digital microscope simulation image 402-0 with a captured image of a photomask to generate a difference image ΔI₀(x, y) as shown in FIG. 4B. For example, the processor 11 subtracts the pixel values of the initial digital microscope simulation image 402-0 by those of the captured image to generate the difference image ΔI₀(x, y). The processor 11 may determine that the initial digital microscope simulation image 402-0 and the captured image are dissimilar according to the difference image ΔI₀(x, y).

As shown in FIG. 4C, the processor 11 may generate an updated rasterized photomask image m¹(x, y) according to the initial rasterized photomask image m⁰(x, y), the difference image ΔI₀(x, y) and the initial diffraction parameters 401-0 using the rasterized photomask image generation model 134. Then, the processor 11 may generate diffraction parameters 401-1 of the rasterized photomask image m¹(x, y) using the diffraction retrieve model 130. The diffraction parameters 401-1 may include an X-direction diffraction parameter and a Y-direction diffraction parameter.

The processor 11 may generate a digital microscope simulation image 402-1 according to the diffraction parameters 401-1 using the digital microscope image simulation model 132, and then compare the digital microscope simulation image 402-1 with the captured image to generate a difference image ΔI₁(x, y), as shown in FIG. 4D. The processor 11 may determine that the digital microscope simulation image 402-1 and the captured image are dissimilar according to the difference image ΔI₁(x, y). The processor 11 may generate an updated rasterized photomask image m²(x, y) according to the rasterized photomask image m¹(x, y), the difference image ΔI₁(x, y) and the diffraction parameters 402-1 using the rasterized photomask image generation model 134.

Then, the processor 11 may generate diffraction parameters 401-2 of the rasterized photomask image m²(x, y) using the diffraction retrieve model 130, as shown in FIG. 4E. The diffraction parameters 401-2 may include an X-direction diffraction parameter and a Y-direction diffraction parameter. The processor 11 may generate a digital microscope simulation image 402-2 according to the diffraction parameters 401-2 using the digital microscope image simulation model 132, and then compare the digital microscope simulation image 402-2 with the captured image to generate a difference image ΔI₂(x, y). The processor 11 may determine that the digital microscope simulation image 402-2 and the captured image are dissimilar according to the difference image ΔI₂(x, y). The processor 11 may generate an updated rasterized photomask image m³(x, y) according to the rasterized photomask image m²(x, y), the difference image ΔI₂(x, y) and the diffraction parameters 402-2 using the rasterized photomask image generation model 134.

Then, the processor 11 may repeatedly perform steps in FIGS. 4A to 4F to generate the n^{th} diffraction parameters 401-n of the n^{th} rasterized photomask image mⁿ(x, y), the n^{th} digital microscope simulation image 402-n and the n^{th} difference image ΔIₙ(x, y), as shown in FIGS. 4G and 4H, until the processor 11 determines that the similarity of the digital microscope simulation image 402-n and the captured image are within the predetermined threshold according to the difference image ΔIₙ(x, y). After determining that the similarity of the digital microscope simulation image 402-n and the captured image are within the predetermined threshold according to the difference image ΔIₙ(x, y), the processor 11 may determine that the rasterized photomask image mⁿ(x, y) is the optimized photomask image and the corresponding n^{th} diffraction parameters 401-n are the optimized diffraction parameters.

Referring to FIG. 4I, the processor 11 may generate a scanner simulation image 410 based on the optimized diffraction parameters 401-n using the scanner image simulation model 136 and compare the scanner simulation image 410 with an original design image 412 (e.g., in the GDS II format) of the photomask to determine whether the scanner simulation image 410 has a printable defect with respect to the photomask. In these embodiments, the scanner simulation image 410 may have a printed defect 411 with respect to the photomask so that the photomask may need to be repaired or re-fabricated.

In some implementations, when the difference image ΔIₙ(x, y) represents that a difference ratio between the corresponding simulation image and the captured image is not less than a pre-determined value (e.g., 1%), it means that the corresponding simulation image and the captured image are dissimilar. When the difference image ΔIₙ(x, y) represents that the difference ratio between the corresponding simulation image and the captured image is less than the pre-determined value (e.g., 3%), it means that the corresponding simulation image and the captured image are similar. For example, the difference image ΔIₙ(x, y) has 10000 pixels, and there are 200 pixels representing the differences between the corresponding simulation image and the captured image. Therefore, the difference ratio between the corresponding simulation image and the captured image is 2% which is not less than 1%. The corresponding simulation image and the captured image are dissimilar. For another example, the difference image ΔIₙ(x, y) has 10000 pixels, and there are 90 pixels representing the differences between the corresponding simulation image and the captured image. Therefore, the difference ratio between the corresponding simulation image and the captured image is 0.9% which is less than 1%. The corresponding simulation image and the captured image are similar.

In some implementations, a number of pixels of the difference image ΔIₙ(x, y) having the same value “0” is less than a pre-determined number (e.g., 350), it means that the initial simulation image and the captured image are dissimilar. The number of pixels of the difference image ΔIₙ(x, y) having the same value “0” is equal to or greater than the pre-determined number (e.g., 350), it means that the initial simulation image and the captured image are similar. For example, the difference image ΔIₙ(x, y) has 400 pixels, and there are 300 pixels having the same value “0”. Therefore, the corresponding simulation image and the captured image are dissimilar because 300 is less than the pre-determined number 350. For another example, the difference image ΔIₙ(x, y) has 400 pixels, and there are 365 pixels having the same value “0”. Therefore, the corresponding simulation image and the captured image are similar because 365 is greater than the pre-determined number 350.

In the embodiments of FIGS. 4A to 4I, the images (e.g., rasterized photomask images and digital microscope simulation images) generated based on the digital microscope image simulation model 132 may have a visible defect (as shown in dot-line frames in FIGS. 4B to 4G) and the scanner image 410 generated based on the scanner image simulation model 136 has the corresponding defect 411. In some embodiments, the images (e.g., rasterized photomask images and digital microscope simulation images) generated based on the digital microscope image simulation model 132 may not have any visible defect but the scanner image 410 generated based on the scanner image simulation model 136 has the corresponding defect 411.

In some embodiments, before comparing the simulation image with the original design image for determining defect, the simulation image may be converted (e.g., by half of a threshold value) to obtain a contour image. Then, the contour image of the simulation image may be compared with the original design image for detecting defect(s).

In some embodiments, the processor 11 may input the diffraction parameters corresponding to the photomask into the digital microscope image simulation model to generate the digital microscope simulation image, and may input the optimized diffraction parameters corresponding to the photomask into the scanner image simulation model to generate the scanner image. In particular, the digital microscope image simulation model may need the set of parameters of illumination, illumination polarization, wavelength, numerical aperture, mask stack, magnification, and CCD pixel size to simulate the digital microscope image, and the scanner image simulation model may need the set of parameters of illumination, illumination polarization, wavelength, numerical aperture, mask stack, magnification, and resist model to simulate the scanner image.

In some cases, illumination parameters (including illuminations and illumination polarizations) respectively applied to the digital microscope image simulation model and the scanner image simulation model may be set as different or set as the same. In particular, changing illumination parameter to the models may be easier than changing illumination of physical hardware. Therefore, when the optimized diffraction parameters are obtained based on the mentioned operations of the disclosure, various types of illumination parameters may be applied to the model (e.g., scanner image simulation model) to see if a printed defect of a photomask exists under different illumination parameters.

In some cases, the wavelengths respectively applied to the digital microscope image simulation model and the scanner image simulation model may not necessarily be set as the same because the wavelengths in the digital microscope device and the scanner device may not necessarily be the same. In some cases, under practical operation, the wavelengths respectively applied to the digital microscope image simulation model and the scanner image simulation model may be set as the same because the wavelengths in the digital microscope device and the scanner device may be the same.

In some cases, the numerical apertures respectively applied to the digital microscope image simulation model and the scanner image simulation model may be different because the numerical apertures of the digital microscope device and the scanner device may be different. In particular, the numerical aperture of the digital microscope device may be larger than the numerical aperture of the scanner so that the digital microscope device may have better resolution because larger numerical aperture may be used to determine more precise diffraction parameters.

In some cases, the mask stacks respectively applied to the digital microscope image simulation model and the scanner image simulation model may be the same because the same photomask may be equipped with the digital microscope device and the scanner device (at different timings.)

In some cases, magnifications respectively applied to the digital microscope image simulation model and the scanner image simulation model may be different. For example, the digital microscope device may have large magnification (e.g., more than 100 nm) and the scanner device may have small magnification (e.g., less than 1 nm.)

In some cases, the CCD pixel size applied to the digital microscope image simulation model may depend on the CCD types used in the digital microscope device.

In some cases, the resist model applied to the scanner image simulation model may correspond to a resist stack arrangement of the photomask. For example, the information of the resist stack may include the stacking of multiple layers, e.g., a silicon substrate, a bottom anti-reflective coating, a photoresist layer and a top anti-reflective coating formed over one another.

In some embodiments, the processor 11 may input the optimized diffraction parameters corresponding to the photomask into a virtual image simulation model to generate a virtual image. In particular, the virtual image simulation model may be the digital microscope image simulation model 132 but using different setting of the set of parameters of illumination, illumination polarization, wavelength, numerical aperture, mask stack, magnification and CCD pixel size. The virtual image simulation model may be the scanner image simulation model 136 but using different setting of the set of parameters of illumination, illumination polarization, wavelength, numerical aperture, mask stack, magnification and resist stack. For example, changing illumination parameter to the models may be easier than changing illumination of physical hardware. Therefore, when the optimized diffraction parameters are obtained based on the mentioned operations of the disclosure, the virtual image simulation model may using an illumination different from the illumination applied to the scanner image simulation model (or the digital microscope image simulation model) to generate the virtual image.

The simulation image may be used for confirming the correctness of the determination of printed defect with respect to the photomask M. For example, the printer defect could be very small so that the printer defect can be seen under some illumination settings but may not be visible under other illumination settings. Therefore, the illumination for calculating Φaᵢ^{xx}(f, g) and Φaᵢ^{yy}(f, g) is adjusted to be different from the illumination for calculating Φsᵢ^{xx}(f, g) and Φsᵢ^{yy}(f, g) so that the simulation image generated based on Φaᵢ^{xx}(f, g) and Φaᵢ^{yy}(f, g) can be compared with the original design image 108 to see if the printed defect exists under different illumination setting.

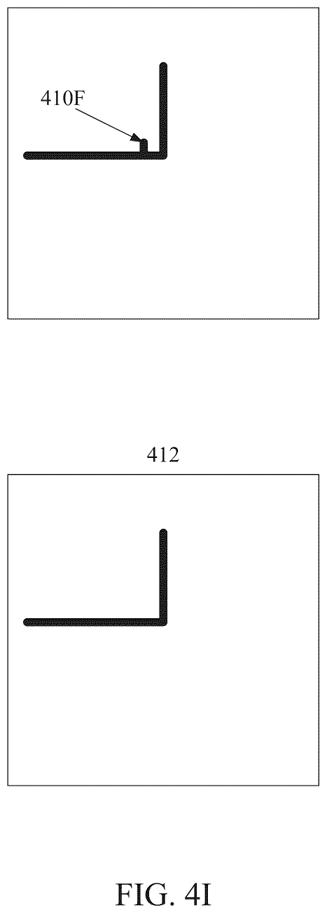

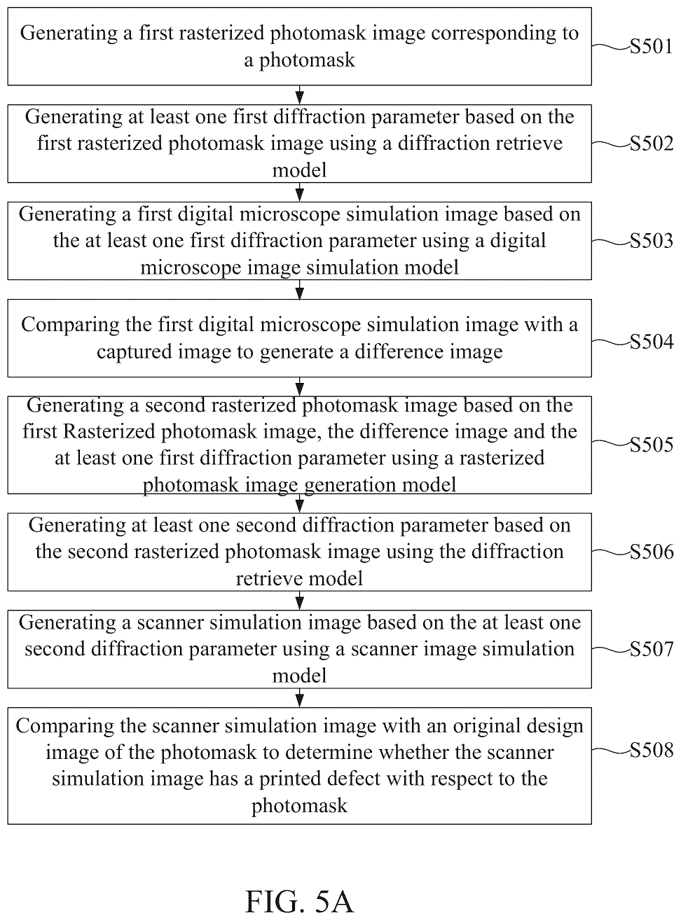

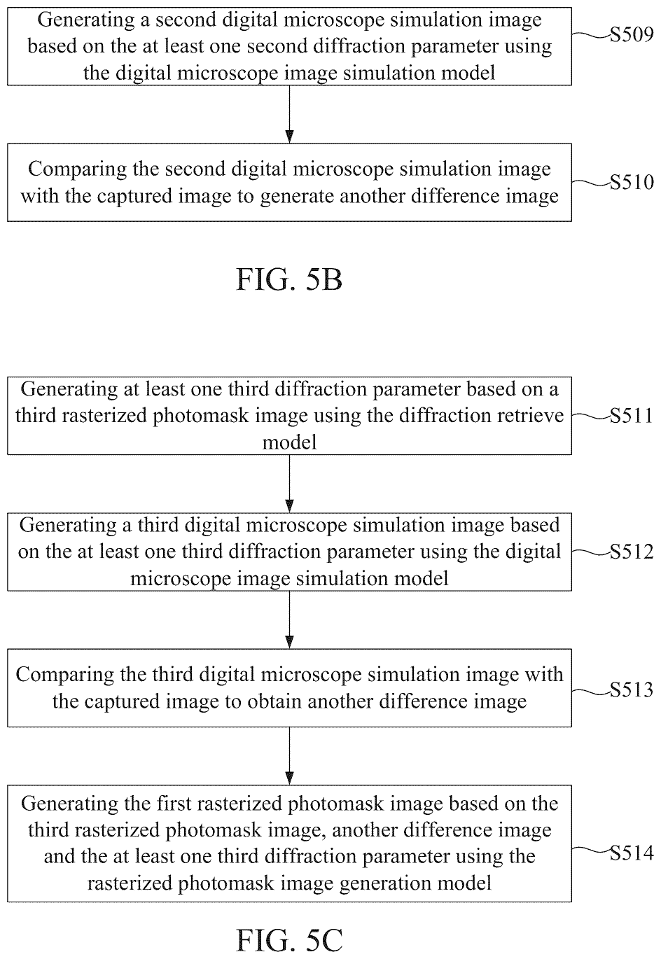

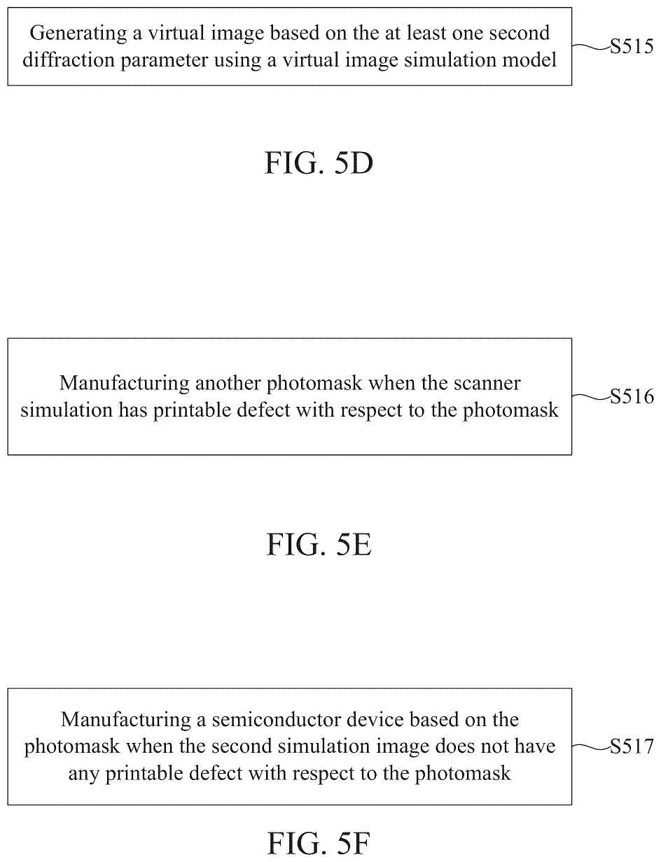

Some embodiments of the present disclosure include a method for determining whether a simulation image has a printed defect with respect to a photomask, and flowchart diagrams thereof are as shown in FIGS. 5A to 5F. The method of some embodiments is implemented by a system (e.g., the system 1 of the aforesaid embodiments). Detailed operations of the method are as follows.

Operation S501 is executed to generate a first rasterized photomask image corresponding to a photomask. Operation S502 is executed to generate at least one first diffraction parameter based on the first rasterized photomask image using a diffraction retrieve model. Operation S503 is executed to generate a first digital microscope simulation image based on the at least one first diffraction parameter using a digital microscope image simulation model. Operation S504 is executed to compare the first digital microscope simulation image with a captured image to generate a difference image. The captured image is generate by an image capture device equipped with the photomask. In these embodiments, a number of pixels of the difference image having a same value is less than a pre-determined threshold (i.e., the first digital microscope simulation image and the capture image may be dissimilar).

Operation S505 is executed to generate a second rasterized photomask image based on the first rasterized photomask image, the difference image and the at least one first diffraction parameter using a rasterized photomask image generation model. Operation S506 is executed to generate at least one second diffraction parameter based on the second rasterized photomask using the diffraction retrieve model. Operation S507 is executed to generate a scanner simulation image based on the at least one second diffraction parameter using a scanner image simulation model. Operation S508 is executed to compare the scanner simulation image with an original design image of the photomask to determine whether the scanner simulation image has a printed defect with respect to the photomask.

In some embodiments, operations S509 to S510 may be performed before the operation S506. Operation S509 is executed to generate a second digital microscope simulation image based on the at least one second diffraction parameter using the digital microscope image simulation model. Operation S510 is executed to compare the second digital microscope simulation image with the captured image of the photomask to generate another difference image. In these embodiments, a number of pixels of the another difference image having a same value is over the pre-determined threshold (i.e., the second digital microscope simulation image and the capture image may be similar). The at least one second diffraction parameter may be the optimized diffraction parameters.

In some embodiments, operations S511 to S513 may be performed before the operation S501. Operation S511 is executed to generate at least one third diffraction parameter based on a third rasterized photomask image (or initial rasterized photomask image) using the diffraction retrieve model. Each pixel of the third rasterized photomask image may have a same value. Operation S512 is executed to generate a third digital microscope simulation image based on the at least one third diffraction parameter using the digital microscope image simulation model. Operation S513 is executed to compare the third digital microscope simulation image with the captured image to generate another difference image. In these embodiments, a number of pixels of the another difference image having a same value is less than the pre-determined threshold. The first rasterized photomask image in operation S501 is generated based on the third rasterized photomask image, the another difference image and the at least one third diffraction parameter using the rasterized photomask image generation model.

In some embodiments, operation S515 may be performed additionally after the at least one second diffraction parameter (i.e., the optimized diffraction parameter(s)) are retrieved. Operation S515 is executed to generate a virtual image according to the at least one second diffraction parameter using a virtual image simulation model.

In some embodiments, operations S516 and S517 may be performed additionally after comparing the scanner simulation image with the original design image of the photomask. Operation S516 is executed to manufacture another photomask when the scanner simulation image has the printable defect with respect to the photomask. Operation S517 is executed to manufacture a semiconductor device based on the photomask when the second simulation image does not have any printable defect with respect to the photomask.

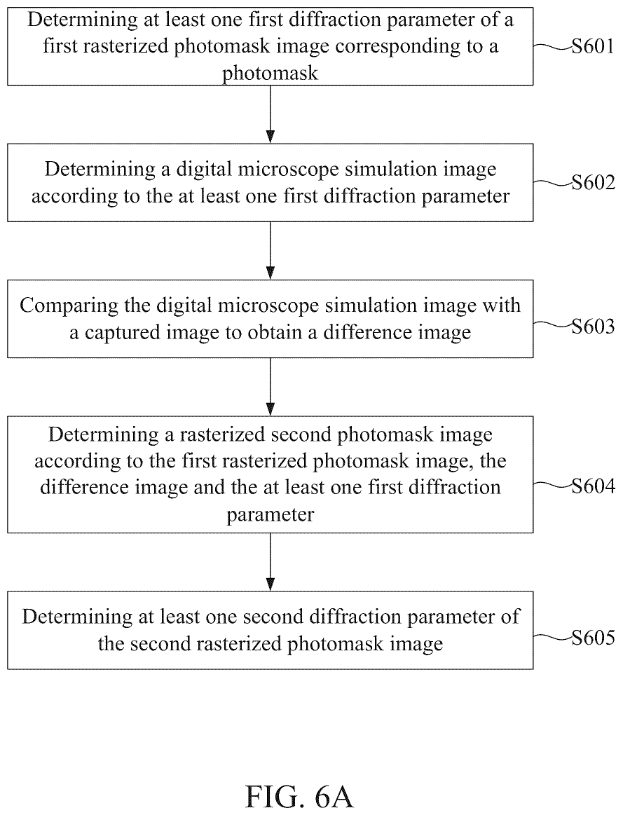

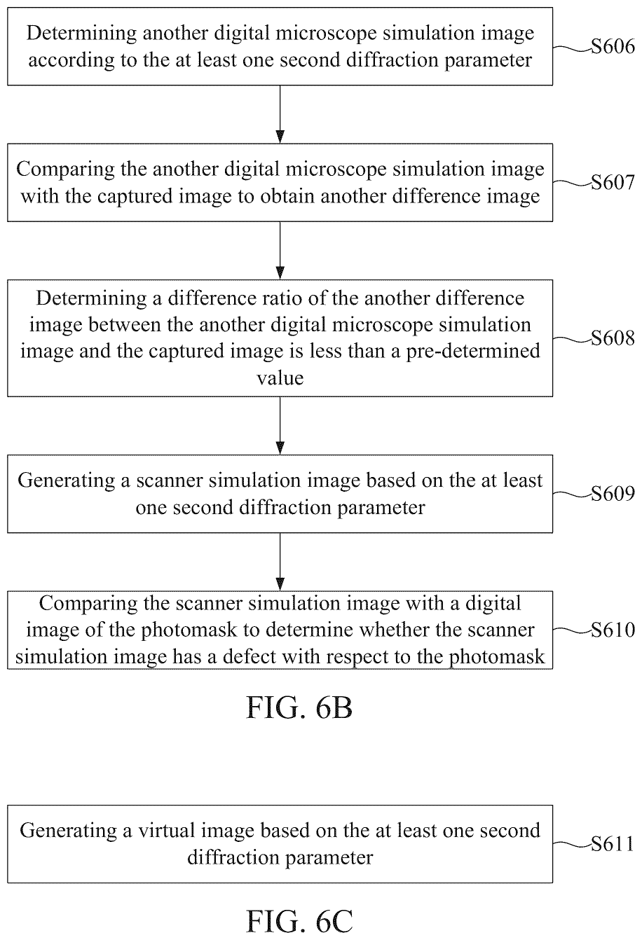

Some embodiments of the present disclosure include a method for optimized diffraction parameter(s) corresponding to a photomask, and flowchart diagrams thereof are as shown in FIGS. 6A to 6C. The method of some embodiments is implemented by a system (e.g., the system 1 of the aforesaid embodiments). Detailed operations of the method are as follows.

Operation S601 is executed to determine at least one first diffraction parameter of a first rasterized photomask image corresponding to a photomask. Operation S602 is executed to determine a digital microscope simulation image according to the at least one first diffraction parameter. Operation S603 is executed to compare the digital microscope simulation image with a captured image of the photomask to generate a difference image. The captured image of the photomask is captured by an image capture device equipped with the photomask. In these embodiments, a difference ratio of the difference image between the digital microscope simulation image and the captured image is not less than a pre-determined value. Operation S604 is executed to determine a second rasterized photomask image according to the first rasterized photomask image, the difference image and the at least one first diffraction parameter. Operation S605 is executed to determine at least one second diffraction parameter of the second rasterized photomask image.

In some embodiments, operations S606 to S609 may be performed after the operation S606 for further optimizing the diffraction parameter(s) and following operations based on the optimized diffraction parameter(s). Operation S606 is executed to determine another digital microscope simulation image according to the at least one second diffraction parameter. Operation S607 is executed to compare the another digital microscope simulation image with the captured image to generate another difference image. Operation S608 is executed to determine a difference ratio of the another difference image between the another digital microscope simulation image and the captured image is less than a pre-determined value. Operation S609 is executed to generate a scanner simulation image based on the at least one second diffraction parameter. Operation S610 is executed to compare the scanner simulation image with an original design image of the photomask to determine whether the scanner simulation image has a defect with respect to the photomask.

In some embodiments, operations S611 may be performed additionally after the at least one second diffraction parameter (i.e., the optimized diffraction parameter(s)) are retrieved. Operation S611 is executed to generate a virtual image based on the at least one second diffraction parameter.

In some embodiments, the at least one first diffraction parameter and the at least one second parameter are determined by applying FT-related formula to the first rasterized photomask image and the second rasterized photomask image respectively.

In some embodiments, the at least one first diffraction parameter includes two diffraction parameters, and the simulation image is determined based on the following formula:

$$I ( x , y ) = {\sum }_{i = 1}^{N} {λ}_{i} {\vert {FT}^{- 1} [ {Φ}_{i}^{x x} ( f , g ) {\hat{m}}^{x x} ( f , g ) + {Φ}_{i}^{y y} ( f , g ) ( f , g ) {\hat{m}}^{y y} ( f , g ) ] \vert}^{2}$$

where I is the simulation image, λᵢ is the i-th transmission cross coefficient (TCC) eigenvalue, Φᵢ^{xx}(f, g) is the i-th TCC eigenfunction for X-direction polarization in a pupil plane, \hat{m}^{xx}(f, g) is one of the two diffraction parameters which is a diffraction parameter being from X-direction polarization at illumination and becoming X-direction polarization on the pupil plane, Φᵢ^{yy}(f, g) is TCC eigenfunction for Y-direction polarization in the pupil plane, and \hat{m}^{yy}(f, g) is the other of the two diffraction parameters which is a diffraction parameter being from Y-direction polarization at illumination and becoming Y-direction polarization on the pupil plane.

In some embodiments, the second photomask image is determined based on the following formula:

$${m}^{k + 1} ( x , y ) = {m}^{k} ( x , y ) - α \frac{d F}{d m} ( x , y )$$

where m^{k+1}(x, y) is the second photomask image, m^{k}(x, y) is the first photomask image, a is a predetermined constant and F is a loss function of m(x, y).

According to some embodiments, a method is provided. The method includes: generating a first rasterized photomask image corresponding to a photomask; retrieving at least on first diffraction parameter based on a first rasterized photomask image using a diffraction retrieve model; generating a digital microscope first simulation image based on the at least one first diffraction parameters using a digital microscope image simulation model; comparing the first digital microscope simulation image with a captured image of the photomask to generate a difference image, wherein the captured image is generate by an image capture device equipped with the photomask; generating a second rasterized photomask image based on the first rasterized photomask image, the difference image and the at least one first diffraction parameter using a rasterized photomask generation model; generating at least one second diffraction parameter based on the second rasterized photomask image using the diffraction retrieve model; generating a second digital microscope simulation image based on the at least one second diffraction parameter using the digital microscope image simulation model; generating a scanner simulation image based on the at least one second diffraction parameter using a scanner image simulation model; and comparing the scanner simulation image with an original design image of the photomask to determine whether the scanner simulation image has a printable defect with respect to the photomask.

According to other embodiments, a method is provided. The method includes: determining at least one first diffraction parameter of a first rasterized photomask image corresponding to a photomask; determining a digital microscope simulation image according to the at least one first diffraction parameter; comparing the digital microscope simulation image with a captured image to generate a difference image, wherein the captured image is generate by an image capture device equipped with the photomask; determining a second rasterized photomask image according to the first rasterized photomask image, the difference image and the at least one first diffraction parameter; and determining at least one second diffraction parameter of the second rasterized photomask image.

According to other embodiments, a system is provided. The system includes a processor and a storing unit. The storing unit stores a program that, when being executed, causes the processor to: generate at least one first diffraction parameter of a first rasterized photomask image corresponding to a photomask; generate a digital microscope simulation image according to the at least one first diffraction parameter; compare the digital microscope simulation image with a captured image to generate a difference image, wherein the captured image is generate by an image capture device equipped with the photomask; generate a second rasterized photomask image according to the first rasterized photomask image, the difference image and the at least one first diffraction parameter; generate at least one second diffraction parameter of the second rasterized photomask image; determine a scanner simulation image according to the at least one second diffraction parameter; and compare the scanner simulation image with an original design image of the photomask to determine whether the scanner simulation image has a defect with respect to the photomask.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A method, comprising:
generating a first rasterized photomask image corresponding to a photomask;
generating at least on first diffraction parameter based on the first rasterized photomask image using a diffraction retrieve model;
generating a first digital microscope simulation image based on the at least one first diffraction parameter using a digital microscope image simulation model;
comparing the first digital microscope simulation image with a captured image of the photomask to generate a difference image, wherein the captured image is generate by an image capture device equipped with the photomask;
generating a second rasterized photomask image based on the first rasterized photomask image, the difference image and the at least one first diffraction parameter using a rasterized photomask generation model;
generating at least one second diffraction parameter based on the second rasterized photomask image using the diffraction retrieve model;
generating a scanner simulation image based on the at least one second diffraction parameter using a scanner image simulation model; and
comparing the scanner simulation image with an original design image of the photomask to determine whether the scanner simulation image has a printable defect with respect to the photomask.

2. The method of claim 1, further comprising:
generating a second digital microscope simulation image based on the at least one second diffraction parameter using the digital microscope image simulation model;
comparing the second digital microscope simulation image with the captured image of the photomask to generate another difference image,
wherein a number of pixels of the difference image having a same value is within a pre-determined threshold,
wherein a number of pixels of the another difference image having a same value is over the pre-determined threshold.

3. The method of claim 1, further comprising:
generating at least one third diffraction parameter based on a third rasterized photomask image corresponding to the photomask using the diffraction retrieve model;
generating a third digital microscope simulation image based on the at least one third diffraction parameter using the digital microscope image simulation model;
comparing the third digital microscope simulation image with the captured image to generate another difference image;
generating the first rasterized photomask image based on the third rasterized photomask image, the another difference image and the at least one third diffraction parameter using the rasterized photomask image generation model.

4. The method of claim 3, wherein each pixel of the third rasterized photomask image has a same value.

5. The method of claim 1, further comprising:
generating a virtual image based on the at least one second diffraction parameter using a virtual image simulation model.

6. The method of claim 1, further comprising:
manufacturing another photomask when the scanner simulation image has the printable defect with respect to the photomask.

7. The method of claim 1, further comprising:
manufacturing a semiconductor device based on the photomask when the second simulation image does not have any printable defect with respect to the photomask.

8. A method, comprising:
determining at least one first diffraction parameter of a first rasterized photomask image corresponding to a photomask;
determining a digital microscope simulation image according to the at least one first diffraction parameter;
comparing the digital microscope simulation image with a captured image to generate a difference image, wherein the captured image is generated by an image capture device equipped with the photomask;
determining a second rasterized photomask image according to the first rasterized photomask image, the difference image and the at least one first diffraction parameter; and
determining at least one second diffraction parameter of the second rasterized photomask image.

9. The method of claim 8, further comprising:
determining another simulation image according to the at least one second diffraction parameter;
comparing the another simulation image with the captured image to generate another difference image;
determining a difference ratio of the another difference image between the another simulation image and the captured image is within a pre-determined threshold.

10. The method of claim 9, further comprising:
generating a scanner simulation image based on the at least one second diffraction parameter; and
comparing the scanner simulation image with an original design image of the photomask to determine whether the scanner simulation image has a defect with respect to the photomask.

11. The method of claim 9, further comprising:
generating a virtual image based on the at least one second diffraction parameter.

12. The method of claim 8, wherein the at least one first diffraction parameter and the at least one second parameter are determined by applying Fourier transform to the first rasterized photomask image and the second rasterized photomask image respectively.

13. The method of claim 8, wherein the at least one first diffraction parameter includes two diffraction parameters, and the digital microscope simulation image is determined based on the following formula:
$$I ( x , y ) = {\sum }_{i = 1}^{N} {λ}_{i} {\vert {FT}^{- 1} [ {Φ}_{i}^{x x} ( f , g ) {\hat{m}}^{x x} ( f , g ) + {Φ}_{i}^{y y} ( f , g ) ( f , g ) {\hat{m}}^{y y} ( f , g ) ] \vert}^{2}$$
where I is the digital microscope simulation image, λᵢ is the i-th transmission cross coefficient (TCC) eigenvalue, Φᵢ^{xx}(f, g) is the i-th TCC eigenfunction for X-direction polarization in a pupil plane, \hat{m}^{xx}(f, g) is one of the two diffraction parameters which is a diffraction parameter being from X-direction polarization at illumination and becoming X-direction polarization on the pupil plane, Φᵢ^{yy}(f, g) is TCC eigenfunction for Y-direction polarization in the pupil plane, and \hat{m}^{yy} (f, g) is the other of the two diffraction parameters which is a diffraction parameter being from Y-direction polarization at illumination and becoming Y-direction polarization on the pupil plane.

14. The method of claim 13, wherein the TCC eigenvalue, the TCC eigenfunction for X-direction polarization and the TCC eigenfunction for Y-direction polarization are determined based on optical parameters corresponding to the image capture device.

15. The method of claim 8, wherein the second rasterized photomask image is determined based on the following formula:
$${m}^{k + 1} = {m}^{k} - α \frac{d F}{d m}$$
where m^{k+1} is the second rasterized photomask image, m^{k} is the first rasterized photomask image, α is a predetermined constant and F is a loss function of m(x, y).

16. The method of claim 8, wherein each pixel of the first photomask image has a same value.

17. A system, comprising:
a processor; and
a storing unit storing a program that, when executed, causes the processor to:
generate at least one first diffraction parameter of a first rasterized photomask image corresponding to a photomask;
generate a digital microscope simulation image according to the at least one first diffraction parameter;
compare the digital microscope simulation image with a captured image to generate a difference image, wherein the captured image is generate by an image capture device equipped with the photomask;
generate a second rasterized photomask image according to the first rasterized photomask image, the difference image and the at least one first diffraction parameter;
generate at least one second diffraction parameter of the second rasterized photomask image;
determine a scanner simulation image according to the at least one second diffraction parameter; and
compare the scanner simulation image with an original design image of the photomask to determine whether the scanner simulation image has a defect with respect to the photomask.

18. The system of claim 17, wherein the program, when being executed, further causes the processor to:
generate at least one initial diffraction parameter of an initial rasterized photomask image corresponding to the photomask;
generate an initial digital microscope simulation image according to the at least one initial diffraction parameter;
compare the initial digital microscope simulation image with the captured image to generate another difference image;
generate the first rasterized photomask image according to the initial rasterized photomask image, the another difference image and the at least one initial diffraction parameter.

19. The system of claim 18, wherein each pixel of the initial photomask image has a same value.

20. The system of claim 17, wherein the difference image represents that a difference ratio between the digital microscope simulation image and the captured image is less than a pre-determined value.
